(19) United States
(12) Patent Application Publication
(10) Pub. No.: US 2005/0281009 A1
(43) Pub. Date: Dec. 22, 2005

(54) Electronic circuit unit for internal combustion engine

(75) Inventors: Kouji Sasaki, Numazu-shi (JP); Tomihiro Iizumi, Numazu-shi (JP)

Correspondence Address: PEARNE & GORDON LLP, 1801 EAST 9TH STREET, SUITE 1200, CLEVELAND, OH, 44114-3108, US

(73) Assignee: Kokusan Denki Co., Ltd., Numazu-shi (JP)

(21) Appl. No.: 10/870,113

(22) Filed: Jun. 17, 2004

(51) Int. Cl. H05K 5/00; H05K 7/14

(52) U.S. Cl. 361/752; 361/757; 361/808

(57) ABSTRACT

An electronic circuit unit for an internal combustion engine including: a printed board; and an electronic component that is mounted to the printed board and configures an electronic circuit for an internal combustion engine, wherein a coupler for connecting a connector mounted to wiring that connects the electronic circuit to an external device is directly mounted to the printed board, the electronic component, the printed board, and the coupler are coated with an injection molded protective coating layer with a connector connection of the coupler being exposed, and the protective coating layer is formed of resin that can be injection molded at low pressure and low temperature.

### TECHNICAL FIELD OF THE INVENTION

The present invention relates to an electronic circuit unit for an internal combustion engine having a structure where a component of an electronic circuit required for controlling the internal combustion engine are resin-molded.

### BACKGROUND OF THE INVENTION

In order to operate an internal combustion engine, an electronic circuit unit has been used including an electronic circuit required for controlling an ignition device for the internal combustion engine or a fuel injection device. A typical electronic circuit unit of this type has been known as an electronic control unit (ECU). The electronic control unit has a structure where a microprocessor, and an electronic component that configures a circuit that forms part of an ignition device or a fuel injection device are mounted to a printed board.

An electronic circuit unit for an internal combustion engine is placed in an engine room or the like, and thus requires resistance to water. For this purpose, in a conventional electronic circuit unit of this type, an electronic component such as a microprocessor is housed in a case together with a printed board, and the printed circuit and the electronic component are resin-molded using resin poured into the case, as described in Japanese Patent Laid-Open Application No. 11-324706 or Japanese Patent Laid-Open Application No. 2004-92598.

However, such a structure requires the case, which makes the structure complex and inevitably increases costs.

As described in Japanese Patent Laid-Open Application No. 2002-260936, an ignition device for an internal combustion engine is proposed wherein a semiconductor element that forms part of the ignition device is coated with a protective coating layer formed by injection molding using thermoplastic resin such as PPS resin (polyphenylene sulfide resin) or transfer molding using epoxy based thermoset resin to configure a module collectively including a plurality of components. However, such a module is housed in a case of a unit together with other components of the unit such as an ignition coil, and further resin-molded using resin cast in the case, and the module does not constitute an electronic circuit unit for an internal combustion engine by itself.

It can be contemplated that a coating layer that coats a component of an electronic circuit unit is injection molded using PPS resin according to the suggestion in Japanese Patent Laid-Open Application No. 2002-260936. However, if the coating layer that coats the component of the electronic circuit is injection molded using PPS resin, shrinkage of resin that occurs during curing of the resin applies great force to the component of the electronic circuit, which increases probability of damage to the component of the electronic circuit, and prevents an increase in yield of the product. Therefore, an electronic circuit unit for an internal combustion engine having a waterproof exterior without any case has not been in practical use.

If a coating layer that coats a component of an electronic circuit is formed by transfer molding using thermoset resin according to the suggestion in Japanese Patent Laid-Open Application No. 2002-260936, curing of the resin takes much time, which inevitably reduces production efficiency of the unit.

### SUMMARY OF THE INVENTION

Therefore, an object of the invention is to provide an electronic circuit unit for an internal combustion engine that can include a waterproof exterior without a case.

According to the invention, there is provided an electronic circuit unit for an internal combustion engine including: a printed board; and an electronic component that is mounted to the printed board and comprises an electronic circuit for an internal combustion engine.

According to the invention, a coupler having a connector connection for connecting a connector mounted to wiring that connects the electronic circuit to an external device is directly mounted to the printed board, and the coupler is connected to the electronic circuit. Then, the electronic component that comprises the electronic circuit, the printed board, and the coupler are coated with an injection molded protective coating layer with the connector connection of the coupler being exposed. The protective coating layer is formed of waterproof resin that can be injection molded at low pressure and low temperature.

The configuration as described above allows the waterproof exterior to be formed without a case, thus providing a waterproof electronic circuit unit for an internal combustion engine at low cost.

The coupler is directly mounted to the printed board, so that the electronic circuit can be connected to the external device simply by connecting the connector, which is mounted to the wiring that connects the unit to the external device, to the coupler, thus facilitating connection between the unit and the external device.

In a preferred aspect of the invention, polyamide based thermoplastic resin is used as resin for forming the protective coating layer.

When the component of the electronic circuit for an internal combustion engine includes a display device, transparent resin is used as the resin for forming the protective coating layer.

Such a configuration allows the protective coating layer to be formed without impairing visibility of the display device.

In another preferred aspect of the invention, a mounting portion is provided in part of the protective coating layer, and a rubber bush into which a metal collar is inserted is embedded in the mounting portion, fastening means such as a screw used for securing the unit to a mounting spot passing through the metal collar.

Such a mounting portion facilitates mounting the unit.

In order to facilitate mounting the unit, a permanent magnet may be secured to the protective coating layer, or a hook and loop fastener may be secured to the protective coating layer.

Other objects and features of the invention will become apparent from the following description with reference to the drawings.

### BRIEF DESCRIPTION OF THE DRAWINGS

The above and other objects and features of the present invention will be apparent from the detailed description of the preferred embodiments of the invention, which is described and illustrated with reference to the accompanying drawings, in which;

FIG. 1A is a plan view of a first embodiment of an electronic circuit unit for an internal combustion engine according to the invention;

FIG. 1B is a sectional view of the unit in FIG. 1A taken along the line 1B-1B;

FIG. 1C is a sectional view of the unit in FIG. 1A taken along the line 1C-1C;

FIG. 2A is a plan view of a second embodiment of an electronic circuit unit for an internal combustion engine according to the invention;

FIG. 2B is a sectional view of the unit in FIG. 2A taken along the line 2B-2B;

FIG. 3 is a side view of the unit in FIGS. 2A and 2B being mounted to a mounting spot;

FIG. 4A is a plan view of a third embodiment of an electronic circuit unit for an internal combustion engine according to the invention;

FIG. 4B is a sectional view of the unit in FIG. 4A taken along the line 4B-4B;

FIG. 5A is a plan view of a fourth embodiment of an electronic circuit unit for an internal combustion engine according to the invention;

FIG. 5B is a sectional view of the unit in FIG. 5A taken along the line 5B-5B;

FIG. 6A is a plan view of a fifth embodiment of an electronic circuit unit for an internal combustion engine according to the invention;

FIG. 6B is a sectional view of the unit in FIG. 6A taken along the line 6B-6B;

FIG. 7A is a plan view of a sixth embodiment of an electronic circuit unit for an internal combustion engine according to the invention;

FIG. 7B is a sectional view of the unit in FIG. 7A taken along the line 7B-7B;

FIG. 8A is a plan view of a seventh embodiment of an electronic circuit unit for an internal combustion engine according to the invention; and

FIG. 8B is a sectional view of the unit in FIG. 8A taken along the line 8B-8B.

### DETAILED DESCRIPTION OF THE PREFERRED EMBODIMENTS

Now, preferred embodiments of the invention will be described with reference to the drawings.

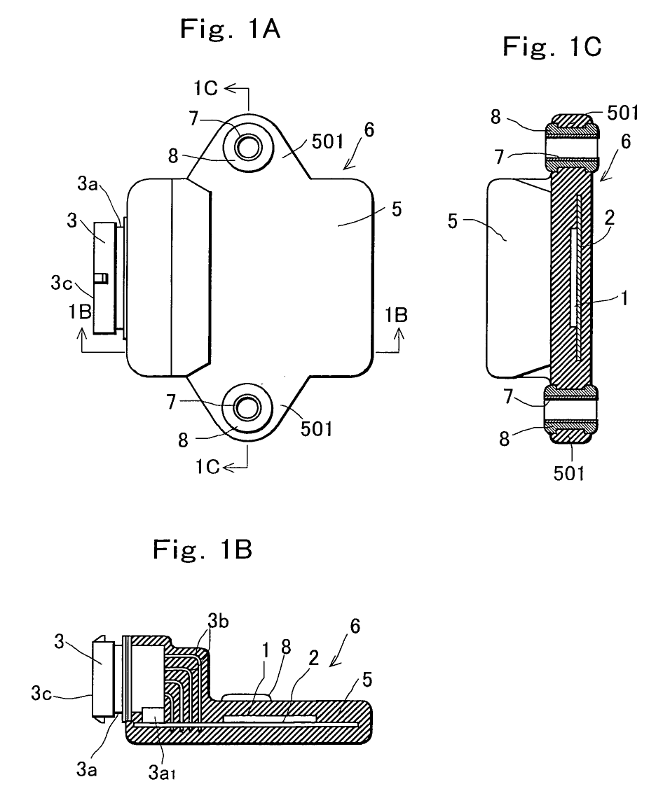

FIGS. 1A to 1C show a first embodiment of an electronic circuit unit for an internal combustion engine according to the invention. In FIGS. 1A to 1C, reference numeral 1 denotes an electronic component placed on and soldered to a surface of a printed board 2, and reference numeral 3 denotes a coupler mounted to the printed board 2.

The coupler 3 is provided to connect a connector (not shown) mounted to wiring (a wire harness) that connects an electronic circuit configured on the printed board by the electronic component 1 to an external device.

The shown coupler 3 includes a coupler body 3a having therein a terminal connected to a terminal of the connector, and a plurality of lead terminals 3b led from an end of the coupler body 3a, and a connector connection 3c to which the unshown connector is connected is provided at the other end of the coupler body 3a.

The coupler 3 is placed on an end of the printed board 2 with the connector connection 3c facing opposite the electronic component 1 in parallel with the surface of the printed board 2, and mounted to the printed board 2 by soldering the lead terminals 3b to a terminal conductor provided on the printed board 2.

In order to firmly support the coupler 3 on the printed board, a base 3a1 having a flat surface abutting against the surface of the printed board is formed integrally with an end of the coupler body 3a, and the base 3a1 is abutted against the surface of the printed board 2 and secured thereto by fastening means such as a screw.

In the invention, the printed board 2, the electronic component 1 and the coupler 3 mounted to the printed board are coated with a protective coating layer 5 injection molded by low pressure and low temperature injection molding using waterproof thermoplastic resin that can be injection molded at low pressure and low temperature, and the printed board 2, the electronic component 1 and the coupler 3 mounted to the printed board 2, and the protective coating layer 5 constitute an electronic circuit unit for an internal combustion engine 6.

The protective coating layer 5 is provided so as to expose at least the connector connection 3c of the coupler for connection of the connector to the coupler 3, and fully coat substantially half the coupler body 3a (portions except the connector connection 3c), the lead terminals 3b of the coupler, the printed board 2, and the electronic component 1. Polyamide based thermoplastic resin is preferably used as resin for forming the protective coating layer 5.

The low pressure and low temperature injection molding using polyamide based thermoplastic resin is also referred to as hot melt molding, and is injection molding at low temperature of about 200° C. and at lower injection pressure than in the case where general injection molding resin such as PPS resin is used. Thus, forming the protective coating layer 5 by the low pressure and low temperature injection molding reduces shrinkage of the resin during curing of the protective coating layer and thus reduces force applied to the electronic component 1, thereby preventing damage to the electronic component 1. The low temperature and the low pressure are applied to a mold when the protective coating layer is molded by the low pressure and low temperature injection molding, thereby reducing cost of the mold used for molding and thus reducing manufacturing cost.

The shown protective coating layer 5 is provided so as to coat each portion of the unit with resin having a minimum thickness required for protecting the electronic component and obtaining mechanical strength of the unit. Thus, the protective coating layer 5 is provided so that an upper surface on a front side of the printed board 2 has an uneven surface so as to match a contour of a component placed on the printed board 2, but a lower surface 5a facing a back side of the printed board on which no electronic component is placed is a flat surface.

In the embodiment in FIGS. 1A to 1C, a pair of mounting portions 501 and 501 are formed integrally with the protective coating layer 5. The mounting portions 501 and 501 include wing-like protrusions protruding symmetrically from widthwise both ends of the unit 6. In each mounting portion 501, a rubber bush 8 into which a metal collar 7 is inserted is embedded with a central axis of the collar 7 being orthogonal to the surface of the printed board 2, fastening means such as a screw used for mounting the unit 6 to a mounting spot passing through the metal collar 7.

Such a rubber bush into which the metal collar is inserted is embedded in the mounting portions 501 and 501, thereby facilitating mounting the unit 6 when mounted to a predetermined mounting spot in an engine room or the like.

In the manufacture of the unit 6 in FIGS. 1A to 1C, the electronic component 1 comprising the electronic circuit is mounted to the printed board 2, the coupler 3 is mounted to the printed board 2, then the printed board 2 to which the electronic component 1 and the coupler 3 are mounted, and the rubber bush 8 into which the metal collar 7 is inserted are placed in an injection molding mold, and polyamide based thermoplastic resin melt is poured into the mold to form the protective coating layer 5.

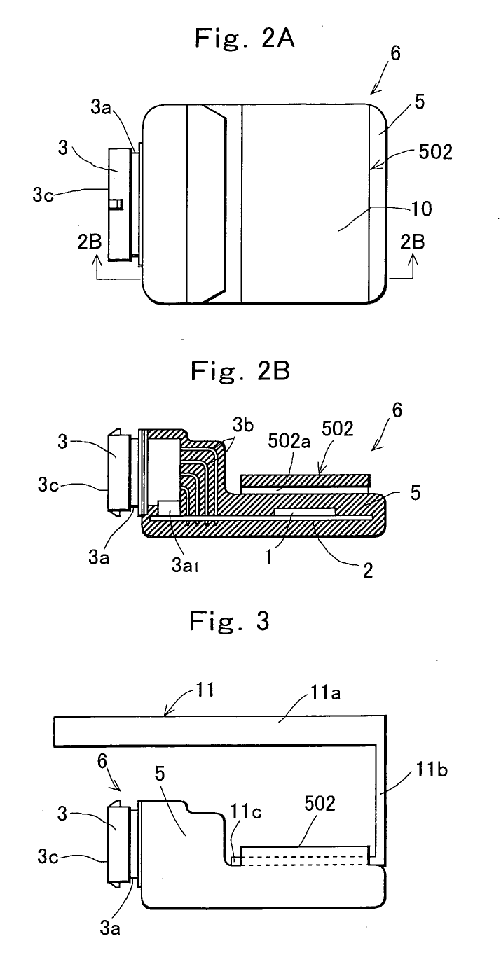

FIGS. 2A and 2B show a second embodiment of an electronic circuit unit for an internal combustion engine according to the invention. In FIGS. 2A and 2B, the same parts as in the embodiment shown in FIGS. 1A to 1C are denoted by the same reference numerals.

In the embodiment in FIGS. 2A and 2B, a mounting portion 502 having a slot 502a therein, into which an insertion formed in a fixture secured to the mounting spot of the unit 6 is inserted, is formed integrally with a top of the protective coating layer 5. The slot 502a inside the mounting portion 502 is provided with both ends thereof being opened so that the insertion of the fixture can be inserted into the slot 502a from opposite the coupler 3. In this embodiment, the mounting portions 501 and 501 provided at widthwise both ends of the protective coating layer 5 in the first embodiment in FIGS. 1A to 1C are omitted. Other configurations are the same as in the first embodiment.

FIG. 3 shows an example of the fixture that can be used for mounting the unit in FIGS. 2A and 2B to the mounting spot. In the example in FIG. 3, a fixture 11 is used integrally provided with a plate-like fixture body 11a secured by a screw or the like to the mounting spot to which the unit is mounted, a bend 11b bent from a tip of the fixture body at the right angle to extend, and a plate-like insertion 11c bent from the tip of the bend 11b toward a rear end of the body 11a to extend.

When the fixture 11 is used, the fixture body 11a is secured to the mounting spot, and then the insertion 11c is inserted into the slot 502a provided in the mounting portion 502 of the unit to secure the unit to the mounting spot via the fixture 11.

The unit 6 comprised as in the embodiment allows the unit to be secured to the mounting spot simply by inserting the insertion 11c of the fixture into the slot 502a of the unit 6, thereby allowing the unit to be easily mounted with a single motion.

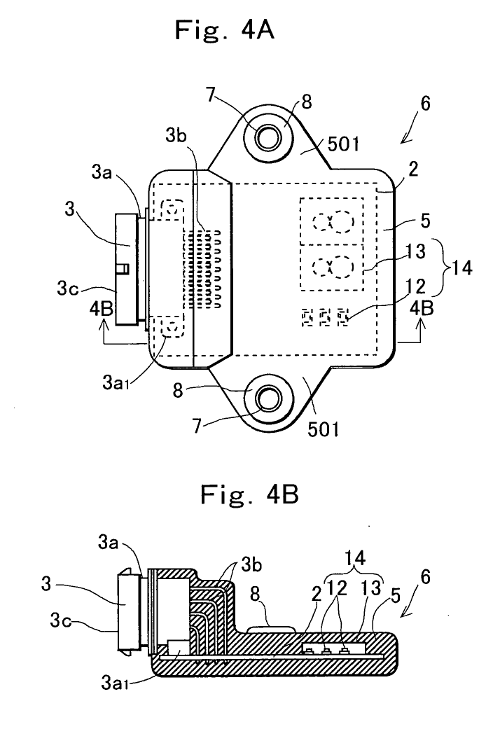

FIGS. 4A and 4B show a third embodiment of an electronic circuit unit for an internal combustion engine according to the invention. In this embodiment, a display device 14 such as a light emitting diode 12 or a seven segment display 13 is placed on the printed board 2 together with the electronic component 1 and the coupler 3, and the display device 14 is connected to the electronic circuit comprised on the printed board.

The printed board 2, the electronic component 1 and the coupler 3 mounted to the printed board 2, and the display device 14 are coated with the protective coating layer 5 injection molded by low pressure and low temperature injection molding using waterproof thermoplastic resin that can be injection molded at low pressure and low temperature, and the printed board 2, the electronic component 1 and the coupler 3 mounted to the printed board 2, and the display device 14, and the protective coating layer 5 constitute an electronic circuit unit for an internal combustion engine 6. For the display device 14 to be visible from outside, the protective coating layer 5 is formed of transparent polyamide based thermoplastic resin.

Mounting portions 501 and 501 are provided in the protective coating layer 5 similar to the mounting portions provided in the first embodiment in FIGS. 1A to 1C, and in each mounting portion 501, a rubber bush 8 into which a metal collar 7 is inserted is embedded.

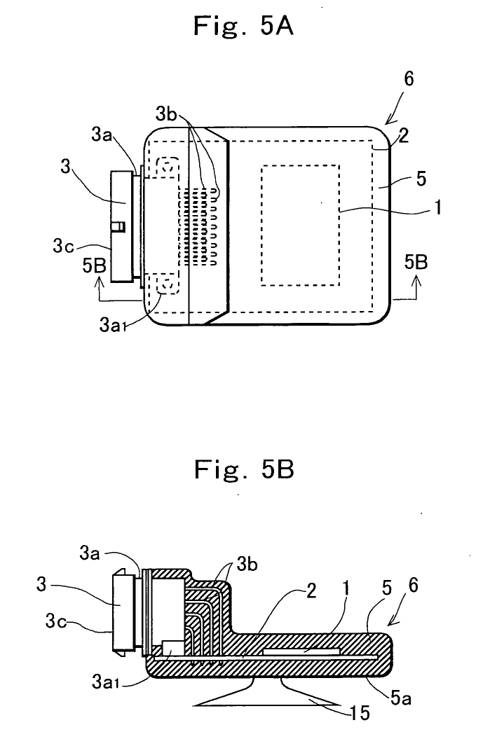

FIGS. 5A and 5B show a fourth embodiment of an electronic circuit unit for an internal combustion engine according to the invention. In this embodiment, a suction cup 15, which is attached to the mounting spot when the unit is secured to the mounting spot, is secured to the lower surface 5a (the surface facing the back side of the printed board 2) of the protective coating layer 5. The mounting portions 501 and 501 provided at widthwise both ends of the protective coating layer 5 in the first embodiment in FIGS. 1A to 1C are omitted. Other configurations of the fourth embodiment are the same as in the first embodiment.

In this embodiment, the suction cup 15 is attached to a mounting surface of the mounting spot to secure the unit 6 to the mounting spot.

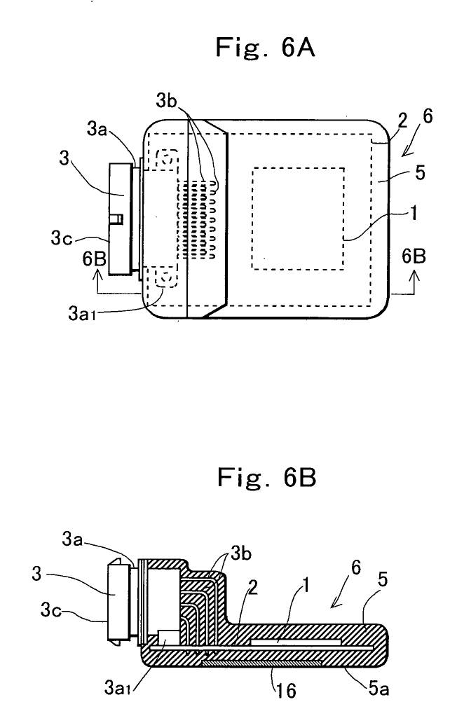

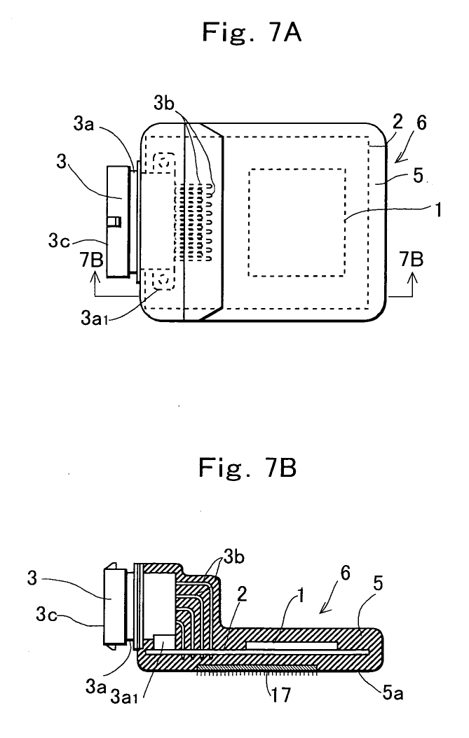

FIGS. 6A and 6B show a fifth embodiment of an electronic circuit unit for an internal combustion engine according to the invention. In this embodiment, a plate-like permanent magnet 16, which is attached to the mounting spot when the unit 6 is secured to the mounting spot, is secured to the lower surface 5a of the protective coating layer 5 facing the back side of the printed board 2. When the protective coating layer 5 is injection molded, the permanent magnet 16 is embedded in the resin that forms the protective coating layer 5, and secured to the protective coating layer 5 with one magnetic pole face 16a being exposed. Other configurations of this embodiment are the same as in the embodiment in FIGS. 5A and 5B.

The permanent magnet 16 secured to the protective coating layer 5 allows the unit 6 to be easily mounted simply by attaching the magnet 16 to the mounting spot when the mounting spot to which the unit 6 is mounted is formed of ferromagnetic material.

The permanent magnet 16 mounted to the lower surface 5a of the protective coating layer 5 facilitates positioning the unit during curing of an adhesive when the lower surface 5a of the protective coating layer 5 is bonded to the mounting spot.

FIGS. 7A and 7B show a sixth embodiment of an electronic circuit unit for an internal combustion engine according to the invention. In this embodiment, a hook and loop fastener 17 is secured to the lower surface 5a of the protective coating layer 5, and the hook and loop fastener 17 is attached to a hook and loop fastener (not shown) secured to the mounting spot to mount the unit 6 to the mounting spot. Other configurations of the sixth embodiment are the same as in the fifth embodiment in FIGS. 6A and 6B.

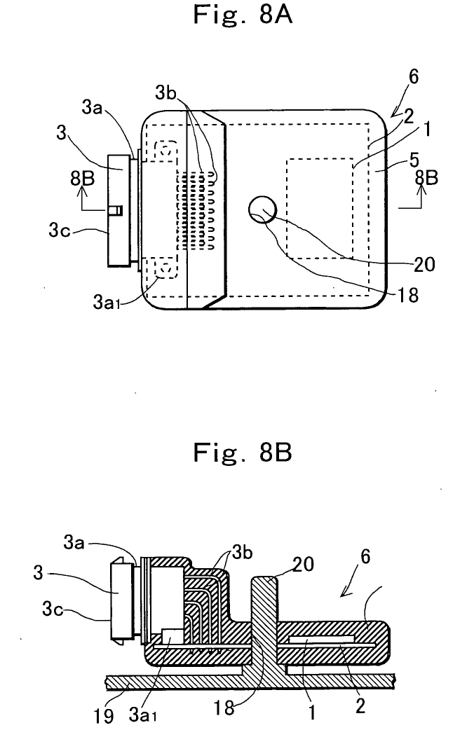

FIGS. 8A and 8B show a seventh embodiment of the invention, and in this embodiment, a mounting hole 18 is drilled through the protective coating layer 5 and the printed board 2. In this embodiment, a bar-like fixture 20 secured to a mounting spot 19 of the unit is inserted into the mounting hole 18 to secure the unit 6 to the mounting spot 19.

In this case, the fixture 20 may be pressed into the mounting hole 18 to secure the unit 6 to the mounting portion, or a stud bolt may be used as the fixture 20 to fasten a nut screwed on the stud bolt against the protective coating layer 5 to secure the unit 6 to the mounting spot 19. When the bar-like fixture 20 is formed of resin, a portion of the fixture 20 protruding beyond the mounting hole 18 may be heated and melted to be crushed, and the crushed portion may be pressed against the protective coating layer 5 to secure the unit to the mounting spot 19.

Other configurations of the seventh embodiment are the same as in the sixth embodiment in FIGS. 7A and 7B.

Although some preferred embodiments of the invention have been described and illustrated with reference to the accompanying drawings, it will be understood by those skilled in the art that they are by way of examples, and that various changes and modifications may be made without departing from the spirit and scope of the invention, which is defined only to the appended claims.

1. An electronic circuit unit for an internal combustion engine comprising:
a printed board; and
an electronic component that is mounted to said printed board and configures an electronic circuit for an internal combustion engine,
wherein a coupler having a connector connection for connecting a connector mounted to wiring that connects said electronic circuit to an external device is directly mounted to said printed board, and said coupler is connected to said electronic circuit,
said electronic component, said printed board, and said coupler are coated with an injection molded protective coating layer with said connector connection of said coupler being exposed, and
said protective coating layer is formed of waterproof resin that can be injection molded at low pressure and low temperature.

2. The electronic circuit unit for an internal combustion engine according to claim 1, wherein the resin for forming said protective coating layer is polyamide based thermoplastic resin.

3. The electronic circuit unit for an internal combustion engine according to claim 1, wherein the component of said electronic circuit for an internal combustion engine includes a display device, and transparent resin is used as the resin for forming said protective coating layer.

4. The electronic circuit unit for an internal combustion engine according to claim 3, wherein the transparent resin for forming said protective coating layer is polyamide based thermoplastic resin.

5. The electronic circuit unit for an internal combustion engine according to claim 1, wherein a mounting portion is provided in part of said protective coating layer, and a rubber bush into which a metal collar is inserted is embedded in said mounting portion, fastening means passing through said metal collar.

6. The electronic circuit unit for an internal combustion engine according to claim 1, wherein a mounting portion having a slot therein, into which an insertion provided in a fixture secured to a mounting spot of said unit is inserted, is formed in part of said protective coating layer.

7. The electronic circuit unit for an internal combustion engine according to claim 1, wherein a suction cup is secured to said protective coating layer.

8. The electronic circuit unit for an internal combustion engine according to claim 1, wherein a permanent magnet is secured to said protective coating layer.

9. The electronic circuit unit for an internal combustion engine according to claim 1, wherein a hook and loop fastener is secured to said protective coating layer.

10. The electronic circuit unit for an internal combustion engine according to claim 1, wherein a mounting hole is drilled through said protective coating layer and said printed board.
